(19) United States
(12) Patent Application Publication
(10) Pub. No.: US 2006/0214164 A1
(43) Pub. Date: Sep. 28, 2006

(54) Semiconductor device and method of manufacturing the device based on evaluation data of test transistors uniformly arranged on test wafer

(76) Inventor: Mikinori Oguni, Kobe-shi (JP)

Correspondence Address: COOPER & DUNHAM, LLP, 1185 AVENUE OF THE AMERICAS, NEW YORK, NY, 10036, US

(21) Appl. No.: 11/390,806

(22) Filed: Mar. 27, 2006

(30) Foreign Application Priority Data
Mar. 28, 2005 (JP) 2005-091022

(51) Int. Cl. H01L 23/58

(52) U.S. Cl. 257/48

(57) ABSTRACT

This patent specification describes a method of manufacturing semiconductor device which includes providing a test wafer having a plurality of test transistors formed on a substrate and uniformly arranged in a substantially whole area of the test wafer, measuring characteristic of the test transistors and implanting onto a manufacturing wafer with adjusted dosage of the implantation at each position of the wafer based on the measured result of the distribution of the characteristic of the test transistors such that each transistor has an equal characteristic.

### FIELD

This patent specification describes a method for manufacturing semiconductor device based on evaluation data of test transistors uniformly arranged on a test wafer.

### DISCUSSION OF THE BACKGROUND

A recent development of semiconductors contributes a rapid growth of unique products such as handy phones, personal digital assistants and so on. It has been studied to develop high density integrated circuits (ICs) and multiple-function devices including analog circuits to realize the products.

To obtain such devices in an economical way, it is a key to make a die smaller and to form transistors having equal characteristic in a whole area of a wafer. More specifically, it is especially important to control a channel implantation which determines a threshold-voltage of MOS transistor. For achieving a precise control of the channel implantation, a distribution of the channel implantation in the wafer is requested to be examined.

A variety of methods to examine the distribution of the channel implantation has been studied and proposed. One example method is to measure a sheet resistance with measurement patterns formed on a surface region of the wafer. Based on the measurement result of the sheet resistance distribution, an appropriate ion dosage is calculated for each position of the wafer. However, a relatively large ion dosage, for example more than 1.0×10¹² cm⁻², is required with this method. If the ion dosage is below 1.0×10¹² cm⁻², it is difficult to obtain a clear distribution data of the ion dosage by measuring the sheet resistances.

Another method is to use a thermal wave detector. Using the thermal wave detector, it is possible to measure the ion dosage even if the ion dosage is below 1.0×10¹² cm⁻². However, a relatively large area is required to measure thermal waves. As a result, a number of measurable points are limited up to a few hundreds with this thermal wave method.

Further, it is proposed to arrange a detector at an ion implantation apparatus to observe an ion dosage during the ion implantation. But there may have discrepancy due to non-direct observation on the target wafer. Therefore, it is strongly desired to provide an evaluation method for a distribution of the ion implantation directly and precisely so as to form the MOS transistors having equal threshold-voltage on a wafer by a feedback of an evaluation data.

### SUMMARY

This patent specification describes a novel method of manufacturing semiconductor device which includes providing a test wafer having a plurality of test transistors formed on a substrate and uniformly arranged in a substantially whole area of the test wafer, measuring characteristic of the test transistors and implanting onto a manufacturing wafer with adjusted dosage of the implantation at each position of the wafer based on the measurement result of the distribution of the characteristic of the test transistors such that each transistor has an equal characteristic.

This patent specification further describes a novel test wafer which includes a substrate and a plurality of test transistors formed on the substrate and uniformly arranged in a substantially whole area of the test wafer.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 illustrates a cross section of a test wafer;

FIG. 2 illustrates a cross section of the test wafer having test transistors thereon;

FIGS. 3A to 3D illustrate the test transistors in cross-section at each process according to the exemplary embodiment;

FIG. 4 illustrates a configuration of an ion implantation apparatus used for a channel dope;

FIGS. 5A to 5C illustrate test results at cases of the test transistor density of 13, 31 and 124 cm⁻² measured with the exemplary method;

FIGS. 6A to 6C illustrate graphs representing measured threshold voltages versus measurement positions on the test wafer of FIG. 5A to 5C; and

FIG. 7 illustrate a measurement result representing the ion dose distribution using a thermal-wave measurement apparatus.

### DETAILED DESCRIPTION OF PREFERRED EMBODIMENTS

In describing preferred embodiments illustrated in the drawings, specific terminology is employed for the sake of clarity. However, the disclosure of this patent specification is not intended to be limited to the specific terminology so selected and it is to be understood that each specific element includes all technical equivalents that operate in a similar manner. Referring now to the drawings, wherein like reference numerals designate identical or corresponding parts throughout the several views, particularly to FIG. 2, a method for manufacturing semiconductor device using a test wafer is described.

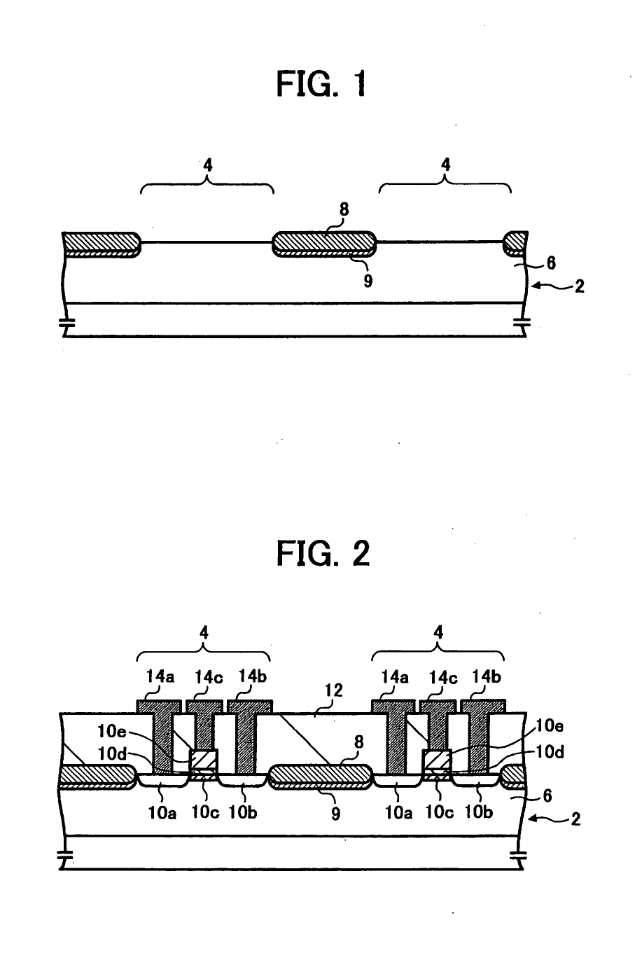

FIG. 1 illustrates a cross section of a test wafer 2. The test wafer includes test transistor forming areas 4 which are uniformly arranged on a surface of the wafer 2. The test transistor forming areas which have an equal conductivity impurity concentration are arranged in the test wafer 2 with a density of, for example, 13 cm⁻². The test transistor forming areas 4 are formed in a P-well 6 which is formed in the whole area of the test wafer 2.

The P-well 6 is formed by implanting a boron with an acceleration energy of 50 KeV and a dose density of 3.4×10¹² cm⁻² onto the surface of the test wafer 2 which has an N-type impurity and has a resistivity of 16 to 24 Ωcm. The test transistor forming area 4 is electrically separated to the other test transistor forming area by a LOCOS (local oxidation of silicon) oxide 8 and a field dope area 9 formed under the LOCOS oxide 8 having boron implanted.

FIG. 2 illustrates a cross section of the test wafer 2 having test transistors thereon. The test transistors have equal structure to each other and are arranged in all the test transistor forming areas 4 of the test wafer 2.

The test transistor includes a source 10a, a drain 10b and a gate 10e. The source 10a and the drain 10b are formed separated with a predetermined distance in the test transistor forming area 4 of the P-well 6. The gate 10e is formed over a channel area 10c which is located at the surface region between the source 10a and the drain 10b via a gate oxide 10d. Phosphorus, for example, is implanted as an N-type impurity into the channel area 10c so as to reduce a the P-type impurity density.

After forming the test transistors, an interlayer insulating film 12, for example BPSG (boro-phospho-silicate-glass), is formed on the test wafer 2. Contact holes are formed at positions corresponding to the source 10a, the drain 10b and the gate 10e. Metal layers 14a, 14b and 14c are formed in each contact holes and on the interlayer insulating film 12. The metal layer 14a is a wiring to draw a potential of the source 10a out. Similarly, the metal layer 14b is a wiring for the drain 10b and the metal layer 14c is a wiring for the gate 10e.

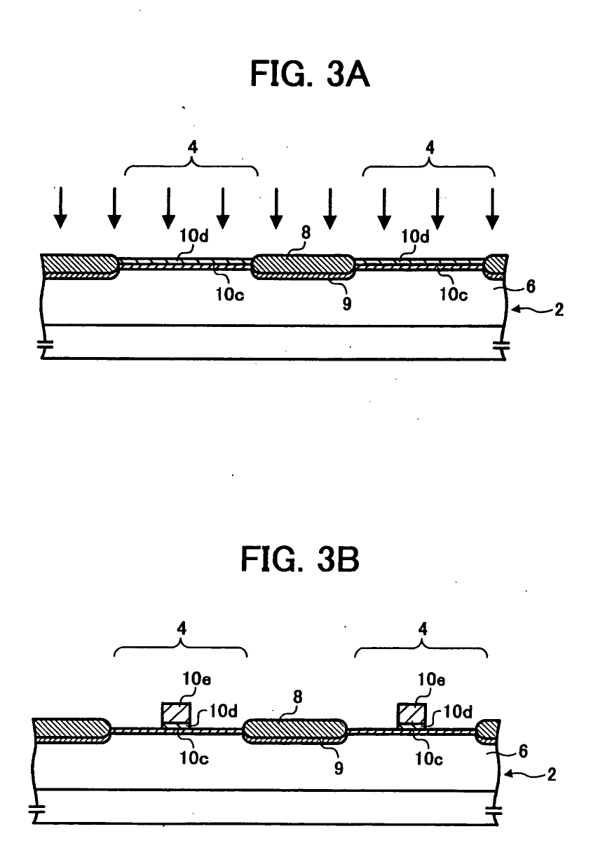

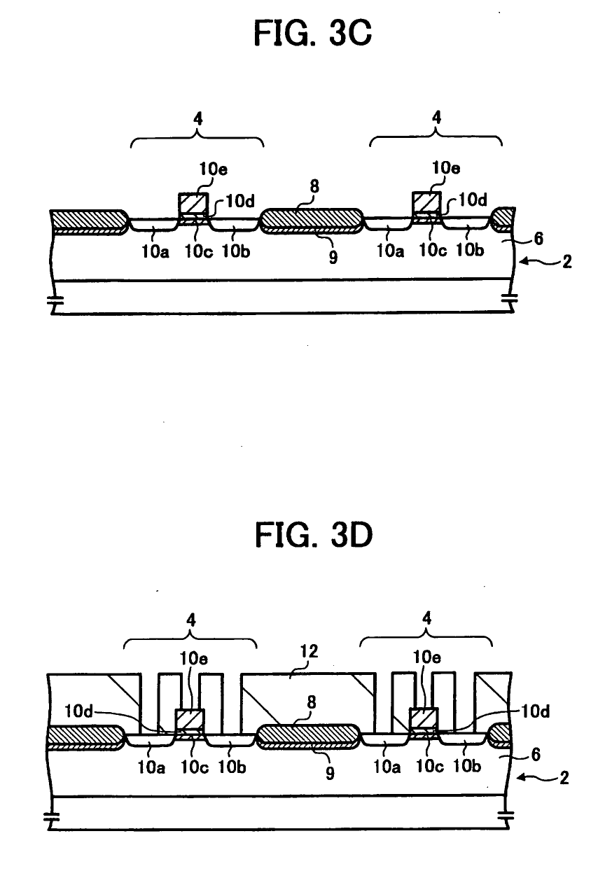

FIGS. 3A to 3D illustrate the test transistors in cross-section at each process according to the exemplary embodiment. The measurement steps of an ion dose distribution will be explained step by step including a preparation of the test wafer referring to FIGS. 3A to 3D.

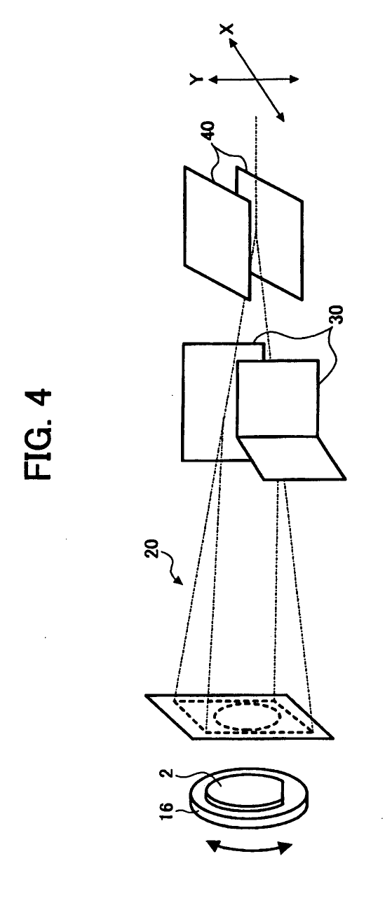

In step 1, the interlayer insulating film 12 is formed with a thickness of 500 A (angstrom) on the surface of the test wafer 2 as explained using FIG. 1. The channel region 10c is formed by implanting ion into the whole area of the test wafer 2 as shown in FIG. 3A. The ion implantation to form the channel region is called a channel dope. In this implantation process, the phosphorus is implanted with the dose energy of 100 KeV and the dose density of 4.6×10¹¹ cm⁻². The channel dope is performed using an ion implantation apparatus having a configuration as shown in FIG. 4.

The ion implantation apparatus includes a wafer stage 16 and deflecting electrodes 30 and 40. The wafer stage 16 holds the test wafer and is rotated during the implantation process. The deflecting electrodes 30 and 40 deflect an ion beam 20 in X and Y directions with an application of an electrostatic force. An impurity is implanted into the whole surface of the wafer 2 by deflecting and scanning the ion beam 20 in the X and Y directions with the rotation of the wafer stage 16.

In step 2, a polysilicon film is deposited with a thickness of 3500 A (angstrom) on the surface of the test wafer 2. The polysilicon film is processed to have a predetermined pattern using a photo-lithography and etching processes so as to form the gates 10e at predetermined positions in the test transistor forming areas 4 as shown in FIG. 3B.

In step 3, phosphorus, for example, is implanted into the test transistor forming area 4 in the P-well 6 by masking with the gate 10e and the LOCOS oxide 8 so as to form the source 10a and the drain 10b with self-aligning to the gate 10e as shown in FIG. 3C.

In step 4, the interlayer insulating film 12 is deposited on the surface of the test wafer 2. The contact holes are formed at positions corresponding to the source 10a, the drain 10b and the gate 10e as shown in FIG. 3D.

In step 5, the metal layers 14a, 14b and 14c are formed in the contact holes and on the interlayer insulating film 12 as shown in FIG. 2.

In step 6, a threshold voltage of the test transistor is measured by changing a voltage of the gate 10e while applying predetermined voltages to the source 10a and the drain 10b. For example, the threshold-voltage of the test transistor is measured by changing the voltage to the gate 10e with a range of 0 to 2 volt while the source 10a is connected to a ground and the drain 10b is applied with 5 volt.

The threshold-voltage of the transistor has a strong dependency of the channel dope. Therefore, the distribution of the channel dope can be measured by measuring each threshold-voltage of the transistors which are uniformly arranged in the whole area of the test wafer 2.

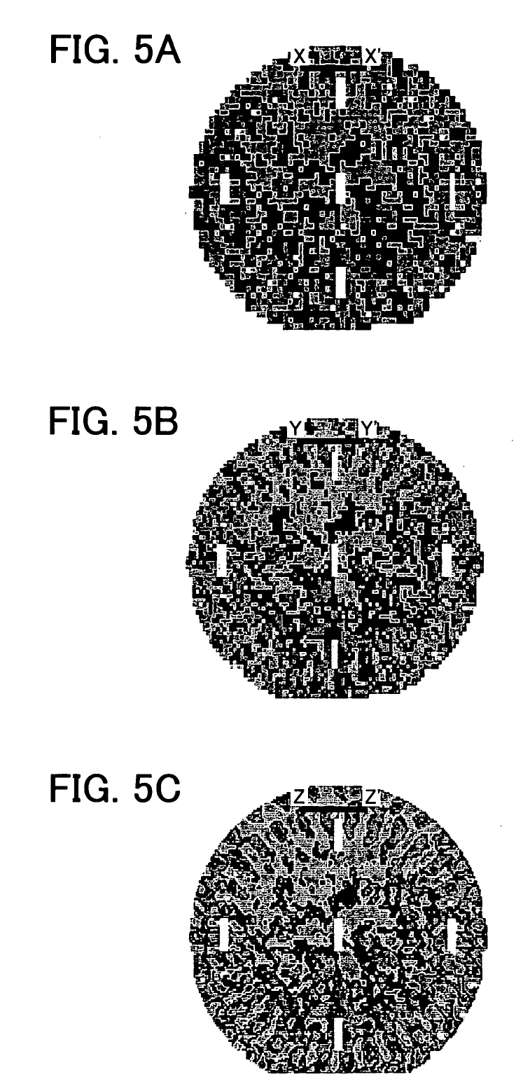

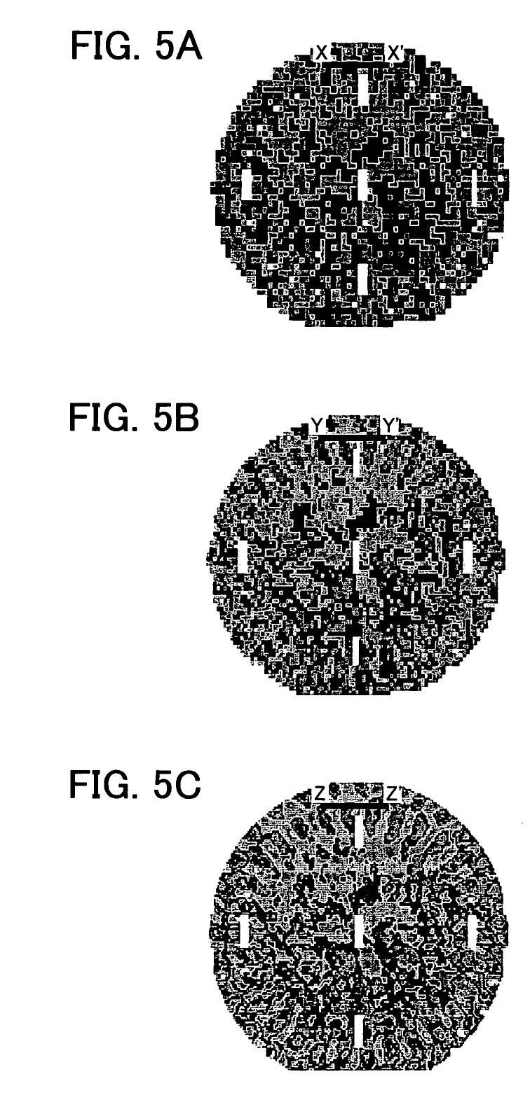

FIGS. 5A to 5C illustrate measurement results representing the distribution of the threshold-voltage by this method. FIG. 5A shows a distribution data at the test transistor density of 13 cm⁻². FIG. 5B shows a distribution data at the test transistor density of 31 cm⁻². FIG. 5C shows a distribution data at the test transistor density of 124 cm⁻².

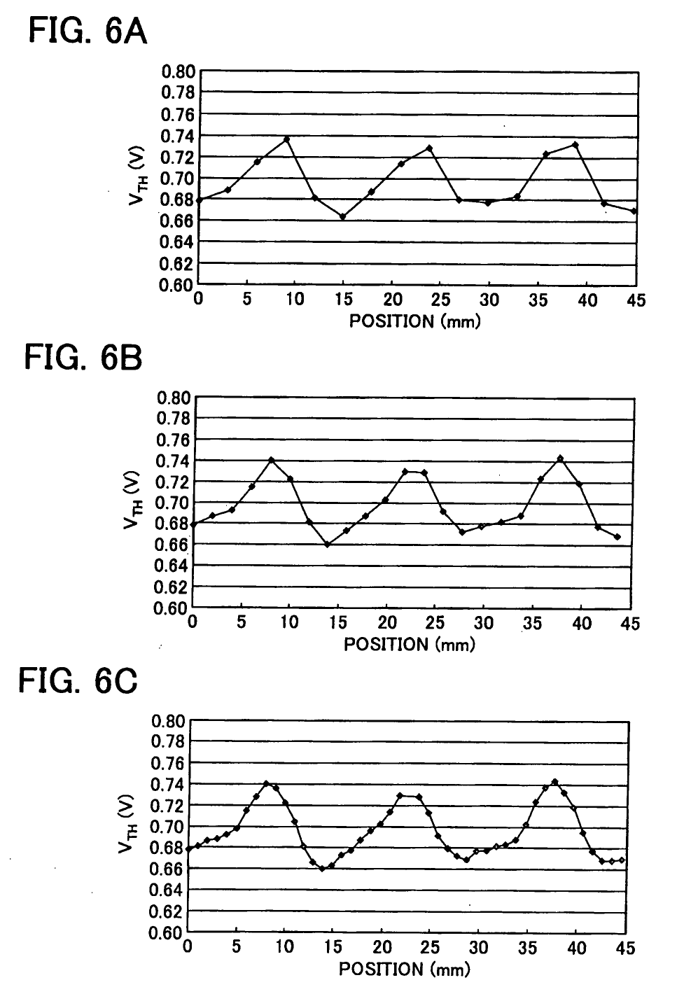

FIGS. 6A to 6C are graphs of measured threshold-voltages versus measurement positions on the test wafer 2 of FIG. 5A to 5C respectively. FIG. 6A represents the data measured at the positions correspond to X to X′. Similarly, FIG. 6B represents the data measured at the positions correspond to Y to Y′. FIG. 6C represents the data measured at the positions correspond to Z to Z′. The vertical line shows the threshold voltage (volt) and the horizontal line shows the measurement position (mm).

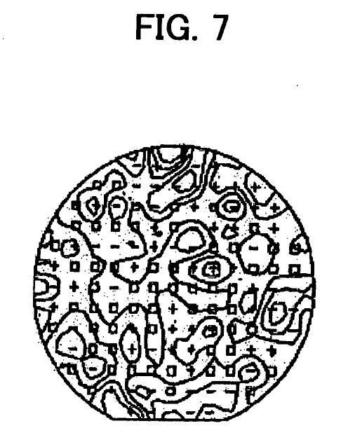

FIG. 7 illustrate a measurement result representing the channel dope distribution using a thermal-wave measurement apparatus for the comparison. The distribution data of the threshold voltage of FIGS. 5A to 5C (i.e., ion dose distribution) are indicating differences more clearly and precisely in comparison to the distribution data as shown in FIG. 7 which is measured by the thermal-wave measurement apparatus.

Observing the threshold voltage data of FIGS. 5A to 5C and FIGS. 6A to 6C in this measurement result, large periodic variations can be found. This phenomenon is presumed due to a synchronization of a part of the rotation speed of the test wafer 2 with a scanning frequency of the ion beam. Based on the measurement results, therefore, it is possible to know that the rotation speed of the test wafer 2 is requested to adjust to the scanning frequency of the ion beam such that the variation of the threshold-voltage is reduced. The acceleration energy and the dose density may be adjusted instead.

Thus, it is possible to precisely evaluate the distribution of the channel dope by measuring the threshold-voltages of the test transistors because the threshold-voltage of the transistor has a strong dependency of the ion dose. Moreover, even if ion dosage is relatively small, the ion dose distribution can be evaluated.

The measured result of the ion distribution is fed back to a manufacturing condition. A channel dope is performed with adjusted dosage of the implantation onto a manufacturing wafer at each position of the wafer such that each transistor has an equal characteristic.

According to the FIGS. 5A to 5C and FIGS. 6A to 6C, more clear result can be obtained with the case of the density of the transistors of 31 cm⁻² in comparison to the case of the density of the transistors of 13 cm⁻². Further, much more clear result can be obtained with the case of the density of the transistors of 124 cm⁻² in comparison to the case of the density of the transistors of 31 cm⁻².

From the measurement results of the FIG. 5A and FIG. 6A, it is possible to evaluate the ion dose distribution if the transistor density to be measured is at least 10 cm⁻². Moreover, it is possible to evaluate the ion dose distribution more precisely if the transistor density to be measured is more than 30 cm⁻² according to the FIG. 5B and FIG. 6B. Furthermore, it is possible to evaluate the ion dose distribution much more precisely if the transistor density to be measured is more than 100 cm⁻² according to the FIG. 5C and FIG. 6C.

Another number of the test transistor density can be employed besides 13, 31 and 124 cm⁻² depending on a requested level. The test transistor forming area 4 may be formed on an N-well instead of the P-well. A P-type wafer may be used instead of the N-type wafer. Ion for the channel dope may be boron and arsenic instead of the phosphorus. Other type of ion implantation apparatus which handles multi-wafers may be used.

Numerous additional modifications and variations are possible in light of the above teachings. It is therefore to be understood that within the scope of the appended claims, the disclosure of this patent specification may be practiced otherwise than as specifically described herein.

This patent specification is based on Japanese patent application, No. 2005-091022 filed on Mar. 28, 2005 in the Japan Patent Office, the entire contents of which are incorporated by reference herein.

What is claimed is:

1. A test wafer comprising:
a substrate; and
a plurality of test transistors formed on the substrate and uniformly arranged in a substantially whole area of the test wafer.

2. The test wafer comprising of claim 1, wherein the test transistor is a MOS transistor and a threshold-voltage of the MOS transistor is measured.

3. The test wafer comprising of claim 1, wherein the test transistor density is at least 10 cm⁻².

4. The test wafer comprising of claim 1, wherein the test transistor density is more than 30 cm⁻².

5. The test wafer comprising of claim 1, wherein the test transistor density is more than 100 cm⁻².

6. A method for evaluating a dosage distribution of ion implantation, comprising the steps of:
providing a test wafer which includes a plurality of test transistors formed on a substrate and uniformly arranged in a substantially whole area of the test wafer; and
measuring characteristic of the test transistors.

7. The method of claim 6, wherein the test transistor is a MOS transistor and a threshold-voltage of the MOS transistor is measured.

8. The method of claim 6, wherein the test transistor density is at least 10 cm⁻².

9. The method of claim 6, wherein the test transistor density is more than 30 cm⁻².

10. The method of claim 6, wherein the test transistor density is more than 100 cm⁻².

11. The method of claim 6, wherein the test wafer is rotated during a channel implantation process.

12. A method for manufacturing semiconductor device, comprising the steps of:
providing a test wafer which includes a plurality of test transistors formed on a substrate and uniformly arranged in a substantially whole area of the test wafer;
measuring characteristic of the test transistors; and
implanting onto a manufacturing wafer with adjusted dosage of the implantation at each position of the wafer based on the measured result of the distribution of the characteristic of the test transistors such that each transistor has an equal characteristic.

13. The method of claim 12, wherein the test transistor is a MOS transistor and a threshold-voltage of the MOS transistor is measured.

14. The method of claim 12, wherein the test transistor density is at least 10 cm⁻².

15. The method of claim 12, wherein the test transistor density is more than 30 cm⁻².

16. The method of claim 12, wherein the test transistor density is more than 100 cm⁻².

17. The method of claim 13, wherein the adjusted dosage of the channel implantation is implanted onto the manufacturing wafer at each position of the wafer based on a measured result of a threshold-voltage distribution of the test MOS transistors such that each MOS transistor has an equal threshold-voltage.

18. The method of claim 13, wherein the test wafer is rotated during the channel implantation process.
